(19) United States
(12) Patent Application Publication
(10) Pub. No.: US 2002/0152436 A1
(43) Pub. Date: Oct. 17, 2002

(54) Digital error mapping circuit and method

(76) Inventor: James Orrin O'Dea, San Clemente, CA (US)

Correspondence Address: Ronald J. Clark, P.C., POBox 8539, Newport Beach, CA, 92658, US

(21) Appl. No.: 10/061,389

(22) Filed: Feb. 1, 2002

Related U.S. Application Data
(60) Provisional application No. 60/266,681, filed on Feb. 5, 2001.

(51) Int. Cl. G11C 29/00

(52) U.S. Cl. 714/723; 714/811

(57) ABSTRACT

A method and apparatus for detecting and mapping digital errors on optical media is provided which includes an invalid symbol detector capable of detecting errors in real time. The method and apparatus further includes the ability to set a run-length mask enabling selective display of specific run-lengths. The method and apparatus of error mapping enables the detection of errors at the time that the data is read and before the data is processed by traditional error detection and correction circuits. Capturing the errors relative to their physical location on the optical media allows the creation of an error map or surface presentation of the errors. The resulting error map displays the location and magnitude of digital errors caused by invalid symbols. The error map allows the test operator to quickly determine the specific location and or distribution of errors on the optical media.

### CROSS-REFERENCE TO RELATED APPLICATION

This application is a continuation-in-part of co-owned and copending application serial No. 60/266,681, filed Feb. 5, 2001, the disclosure of which is incorporated herein by reference.

### BACKGROUND OF THE INVENTION

1. Field of the Invention

The present invention relates generally to a circuit and method for detecting and mapping digital errors on optical media, and more specifically, to a circuit and method for detecting digital errors on optical media caused by invalid symbols and relating the detected errors to their physical location on the media.

2. Prior Art

Mapping of digital errors on optical media can be very useful in the quality control of optical media manufacturing. The mapping of digital errors displays the distribution and concentration of errors occurring on the optical media. A certain level of random digital errors can be expected and is tolerated in the production of optical media. With error mapping the optical media can be easily inspected for localized flaws that cause a concentration of digital errors.

Currently, mapping of errors on CD format optical media has been done by monitoring the error flag outputs of the large scale integrated (LSI) circuits that perform demodulation, de-interleaving, error detection and error correction on the optical media player. The traditional method to map errors on CD format can be done with reasonable resolution due to the small error correction code (ECC) block size and interleaving of the data is minimal at the first level of error detection and correction.

The CD format has a single level of interleave at the first error decoder. Interleaving of the data on the CD consists of a single block delay of alternate symbols at the first decoder. The block size at the first decoder on the CD player is relatively small consisting of 32 symbols. With minimal interleaving and a small ECC block size the errors that are reported can be related closely to the physical location on the optical media as the data is read. The size of the ECC block and the single level of interleaving at the first decoder limit the resolution of the error map. With the CD format using the error flags, an error can be determined to have occurred within two ECC blocks or 64 symbols of data read from the optical media, equal to a linear distance of approximately 0.4 mm in one of the tracks on a CD.

Modern optical media formats such as DVD implement a much larger FCC block size. The DVD ECC block is made up of rows and columns of interleaved data. There are a total of 37,856 symbols in each DVD ECC block, equal to a linear distance of approximately 80 mm in one of the tracks on the DVD. The interleaving of the data is done to make the system more robust by limiting the effect of burst errors or localized defects on the error correction system. Interleaving the ECC block will spread the errors caused by a flaw or surface scratch over many ECC rows, thereby making the errors easier for the error correction system to detect and correct. The error flags reported by the LSI circuits of the DVD player are delayed, and are reported for each row and column of the ECC block after each ECC block is built from the interleaved data. The fact that the error flags are delayed and reported for all rows and then all columns of the ECC block make the relation of error flags to localized defects impossible, and therefore can not be used to map the errors.

A new method of error detection is required to map optical media errors on formats such as DVD that support large ECC block sizes. The resolution of error maps of optical media can be greatly improved by detecting errors at the run-length or symbol level rather than at the ECC block level. Detecting errors and mapping errors in real time at the run-length or symbol level could improve the resolution of the current method of error mapping on CD format optical media by a factor of approximately 100 and error mapping on DVD format optical media by a factor of approximately 10,000.

### SUMMARY OF THE INVENTION

Briefly, in accordance with the invention, a method for detecting and mapping digital errors on optical media is provided which includes an invalid symbol detector capable of detecting errors in real time. The inventive method of error mapping enables the detection of errors in the serial digital data stream as the data is read, before the data has been de-interleaved, placed in ECC blocks, and processed with traditional error detection and correction circuits. The invalid symbol detector circuit is responsive to the data bus for monitoring the bit stream substantially direct from the source of digitally encoded data and for identifying one or more invalid symbols from the digitally encoded bit patterns. Capturing the errors relative to their physical location on the optical media allows the creation of an error map or surface presentation of the errors. The resulting error map displays the location and magnitude of digital errors caused by invalid symbols. The error map allows the test operator to quickly determine the specific location and or distribution of errors on the optical media. The unique method also includes the ability to set a run-length mask, enabling selective detection and thus eventual display of specific run-length violations.

Data may be stored on optical media as a spiral of pits and lands. The data is typically encoded as eight-to-fourteen modulation or “EFM” on compact disc format (CD), and eight-to-sixteen modulation on digital versatile disc format (DVD) which is sometimes referred to as “EFM+”. EFM and EFM+ are very similar in that each 8-bits of data is converted into fourteen or sixteen channel bit symbols respectively. In EFM and EFM+ the channel bit patterns that are used to represent the original data have run-length restrictions. Also, in EFM and EFM+ there are many more channel bit patterns possible than are used to represent the original 8-bit data values. In EFM less that two-percent of the possible 14-bit patterns are used to represent the original 8-bit data values. In EFM+ less than one percent of the possible 16-bit patterns are used to represent the original 8-bit data values. When digital errors occur in EFM or EFM+ many of the errors will be seen as invalid channel bit patterns or run-length violations. An invalid channel bit pattern is called an invalid symbol in the data stream. A channel bit pattern having a run-length violation is also called an invalid symbol in the data stream. Therefore, a high percentage of the digital errors on optical media can be detected by looking for the existence of invalid channel bit patterns or run-length violations in the bit stream as it is read from the optical media using the inventive method. The inventive method can detect invalid channel bit patterns or run-length violations with at least logic gates or a look-up table.

The inventive method detects data errors on optical media by monitoring the bit stream from the DVD ROM drive as the optical media is read. By monitoring the bit stream and detecting errors as they relate to the position of the read head relative to the optical media, mapping of errors is possible.

The digital error map created by the inventive method is made up of at least one error map array. Each array is made up of one or more elements. Each element is a summation of errors collected from a localized area, defined by a fixed linear distance and fixed radial distance. Thus each element holds information that will be displayed in the digital error map. The sample size linear distance may be set by the number of PLL clock cycles per sample. The linear resolution of samples per rotation of the optical media is determined by the sample size. A single PLL clock cycle represents a very small linear distance in the rotation of the optical media, so the sample size is typically set to 1000 or more PLL clock cycles.

To map digital errors, at least one fixed rotational reference point is required so the resulting map can be related directly to the surface of the optical media. The tach or once around signal from the DVD ROM drive can be used as a fixed rotational reference point for the digital error map. The fixed reference point is used to reset the element array pointer of the error map array back to the first location or element of the error map array. Using a single rotational reference point, the length in elements of the error map array is equal to the number of samples in each rotation of the optical media.

The radial resolution of elements of each array of the optical media is determined by the rotations per array. A single rotation of optical media causes a very small change in radial distance, such that rotations per array are typically set to 100 or more.

The element value in the error map array may be incremented if an invalid symbol or invalid channel bit run-length representing a digital error is detected during the corresponding sample. For example, with one hundred rotations for each error map array position, the maximum value of any error map array element could be one hundred in the event that the length of each track was one symbol and each symbol was invalid.

The size or length in elements of the error map arrays will increase when optical media is played from the inner diameter to the outer diameter. This is directly correlated to the use of a disc using constant linear velocity. As the PLL control signals are being generated at a constant rate, if is well known that the inner diameter of a disc contains fewer PLL control signals than an outer diameter. The person skilled in the art would then determine the length of the track(s) and the number of adjacently positioned tracks to assign to an element in the array. The value stored in each error map array element can be used to determine the shade or color of the pixel that is displayed on the monitor or the dot that is printed. The shade or the color of the pixel or dot can therefore be used as a visual indicator of the magnitude of the error(s) detected. Each error map array is converted into a circular band of pixels or dots, each oriented to the fixed rotational reference point, forming the complete digital error map.

In review, the error map array is provided with a plurality of storage elements. Sufficient elements are provided to store errors for each invalid symbol or each invalid run-length violation detected directly from the optical media. The laser light beam point of input with the data carrying surface of the optical media can be easily calculated by use of the tack or once around signal stored in the optical disc or calculated by the optical disc drive, in combination with the number of PLL clock cycles generated or sensed since the last tack signal.

If individual errors are to be detected and displayed, then the error map array would have enormous capacity. Since usually that is not the case, then the errors from a localized area is sufficient. A localized area can be a sequential length along one track as defined by the predetermined number of PLL clock cycle. A localized area can also be defined as an area containing a number of tracks and both beginning and ending a fixed time or distance from the tack signal. A person skilled in the art can determine the bounds of such a localized area. In this later case, thirty tracks can be scanned for invalid symbols and each scan may last for 30 PLL clock cycles per track. In this manner, 900 symbols are looked at and the invalid symbols in this sample are counted or summarized.

### OBJECTS OF THE INVENTION

It is therefore a principal object of the present invention to provide a circuit and method for detecting, storing, and mapping errors as the bit stream is read from optical media.

It is also an object of the present invention to provide a circuit and method capable of detecting and mapping digital errors before the optical media data is processed by traditional error detection and correction circuits.

It is another object of the present invention to provide a circuit and method to allow the selection of specific channel bit run-lengths to be detected, stored and mapped.

It is another object of the present invention to provide a circuit and method for creating and displaying an error map of optical media that relates directly to the surface of the optical media.

It is another object of the present invention to provide a circuit and method for storing specific channel bit run-lengths detected in the bit stream read from optical media in a memory buffer that relates directly to the linear and radial position of the of the detected run-length on the optical media.

It is another object of the present invention to provide a new and novel format for displaying the errors taken from a digital data source that is spread over a substantially large sample area.

It is another object of the present invention to provide a new and novel format for displaying the errors taken from a digital data source with means for indicating the number of errors per area in the tangential and or radial position.

### BRIEF DESCRIPTION OF THE DRAWINGS

Additional features and advantages of the invention will be made apparent from the following detailed description of a preferred embodiment, which proceeds with reference to accompanying drawings.

FIG. 1 is a DVD error mapping system block diagram.

FIG. 2 is a DVD digital error map ISA hardware interface block diagram.

FIG. 3 is a DVD digital error map ISA interface invalid symbol detector register block diagram.

FIG. 4 is a schematic of 1T, 2T, 12T, 13T and 15T+ invalid run-length detect and hold circuits.

FIG. 5 is a schematic of an invalid run-length mask register.

FIG. 6 illustrates pits, lands, NRZI and NRZ encoding.

FIG. 7 is an ISA hardware flow chart for creating an error map array.

FIG. 8 is a DVD digital error map ISA interface system software flow chart for creating a DVD error map.

### DETAILED DESCRIPTION OF THE PREFERRED EMBODIMENT

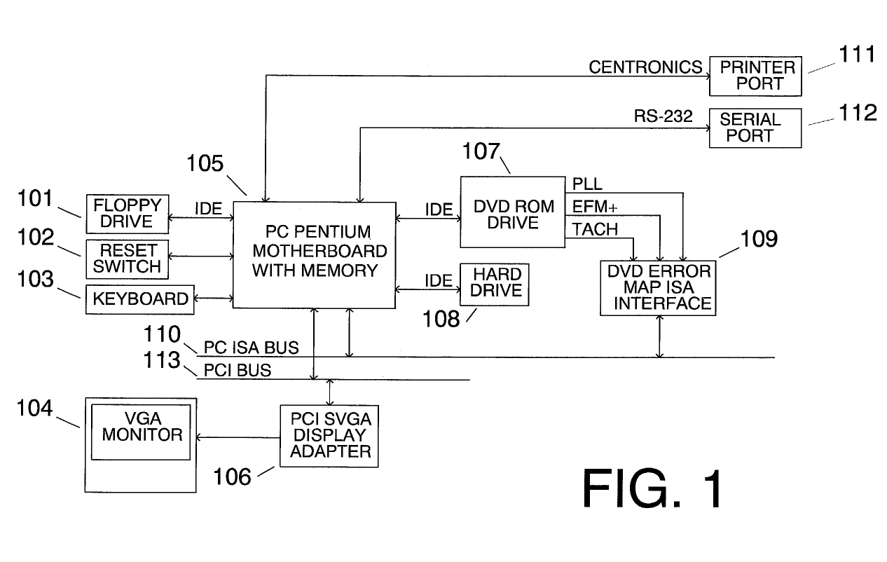

With reference to FIG. 1, a DVD error mapping system according to the preferred embodiment of the invention is detailed with circuits simplified for clarity. The DVD error mapping system includes several components commonly found in personal computer (PC) systems. The components commonly found in a PC include a Pentium motherboard with memory 105, floppy drive 101, keyboard 103, reset switch 102, hard drive 108, display adapter 106, VGA monitor 104, PC ISA bus 110, printer port 111, serial port 112, and PCI bus 113. In addition to the standard PC components is a DVD ROM drive 107, and an unique DVD error mapping interface 109 installed in an Industry Standard Architecture (ISA) 110 back plane slot on the PC Pentium motherboard 105. The DVD ROM drive 107 provides the source of several signals that are required by the DVD error-mapping interface 109. The signals that are required from the DVD ROM drive 107 are the EFM+, phase lock loop (PLL) clock, and tach signal. The EFM+ signal represents the digitally encoded data stream.

The floppy drive 101 is connected to the PC Pentium motherboard 105 and provides a means for reading data stored on floppy disks and or writing data to floppy disks. The reset switch 102 is connected to the PC Pentium motherboard 105, and provides a means for a user hardware reset of the PC Pentium motherboard 105. The keyboard 103 provides a means for user input to the PC. The video graphics array (VGA) monitor 104 is connected to the peripheral component interconnect (PCI) super video graphics array (SVGA) display adapter, and provides a means for the video display of data from the PC Pentium motherboard 105. The PC Pentium motherboard 105 is connected to the floppy drive 101, reset switch 102, keyboard 103, SGVA display adapter 106, DVD ROM drive 107, hard drive 108, DVD error map ISA interface 109, PC ISA bus 110, printer port 111, serial port 112, and PCI bus 113. The PC Pentium motherboard 105 includes memory and provides a means for executing software programs, processing data, and storing data. The PCI SVGA display adapter 106 is connected to the PC Pentium motherboard 105 by the PCI bus 113 and provides a means for the PC Pentium motherboard 105 to control the display of data and graphics on the VGA monitor 104. The DVD ROM drive 107 provides the PLL clock signal as a source of the start and stop period representing the duration of a channel bit in the bit stream. The DVD ROM drive 107, as a source of digital encoded data consisting of a serial stream of channel bits of said duration having at least channel bit patterns and said patterns having run-length restrictions. The bit stream that is supplied by the DVD ROM drive 107 is seen as a serial stream of channel bits grouped in to channel bit patterns forming EFM+ symbols. The DVD ROM drive 107 as a source of the fixed rotational reference signal representing the tach or at least once around index point of the optical media as it is played. The hard drive 108 is connected to the PC Pentium motherboard 105 and provides a means to store and retrieve data such as files or software programs. The DVD error map ISA interface 109 is connected to the PC Pentium motherboard 105 providing a means for reading and writing DVD error map ISA interface registers 109. The DVD error map ISA interface 109 also receives the EFM+, PLL clock and tach signals from the DVD ROM drive 107. The printer port 111 is connected to the PC Pentium motherboard 105 and provides a means to connect the PC Pentium motherboard to a printer. The serial port 112 is connected to the PC Pentium motherboard 105 and provides a means for connection to serial devices such as a serial mouse for user input and control. The PCI bus 113 is connect to the PC Pentium motherboard 105 and provides a means to communicate to the PCI SVGA display adapter 106.

Data is typically stored on optical media as a spiral of pits and lands. The DVD ROM drive uses an optical head assembly to read the reflective contrast between pits and lands on the optical media. The reflective contrast is converted to a proportional electrical signal voltage level that is seen as a high frequency (HF) analog wave as the optical media is played.

The EFM+ signal provided by the DVD ROM drive 107 represents the non-return-to-zero-inverted (NRZT) encoded digital signal that results from slicing the (HF) signal at the zero duty cycle crossing point. Lands relate to the asserted state and pits relate to the negated state of the NRZI encoded digital signal. The PLL clock provided by the DVD ROM drive 107 is locked to the edges in the EFM+ data and is used by LSI circuits in the DVD ROM drive 107 to receive and decode the EFM+ signal.

In EFM+ encoding, the run-lengths used to represent the EFM+ symbols are commonly referred to by their length in channel bits or PLL clock cycles. A pit or land that is 3 channel bits in length would be referred to as a 3T. EFM+ encoding has 10 valid run-lengths, which include 3T, 4T, 5T, 6T, 7T, 8T, 9T, 10T, 11T, and 14T pit and land lengths.

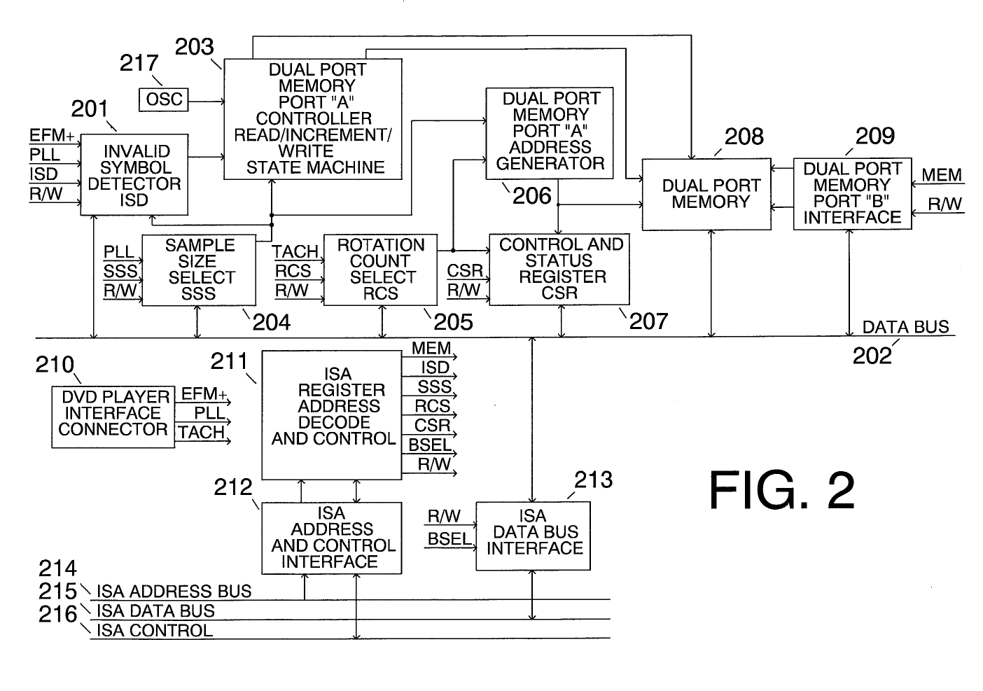

With reference to FIG. 2, a DVD digital error map ISA hardware interface block diagram is detailed with circuits simplified for clarity. The DVD digital error map ISA hardware interface includes an invalid symbol detector 201, data bus 202, dual port memory port “A” controller 203, sample size select 204, rotation count select 205, dual port memory port “A” address generator 206, control and status register 207, dual port memory 208, dual port memory port “B” interface 209, DVD player interface connectors 210, ISA register address decode and control 211, ISA address and control interface 212, ISA data bus interface 213, ISA address bus 214, ISA data bus 215, ISA control bus 216 and oscillator 217. The PC Pentium motherboard 105 communicates with DVD error map ISA interface 109 on the ISA bus 110 that includes ISA address 214, ISA data 215 and ISA control 216.

The invalid symbol detector (ISD) 201 receives the EFM+ bit stream and PLL clock from the DVD ROM drive 107. The ISD 201 is responsive to the data bus for monitoring the bit stream substantially direct from the source of digitally encoded data. The PLL clock defines the start and stop period of time representing a single channel bit in the EFM+ encoded data bit stream. The bit stream supplied by the DVD ROM drive 107 is seen as a serial stream of channel bits grouped in to channel bit patterns forming EFM+ symbols. EFM+ is a run-length limited encoded data format. The ISD 201 is used to detect invalid symbols or invalid channel bit run-lengths in the EFM+ bit stream. The ISD is responsive to the internal data bus 202, that is connected down stream to the ISA data bus 110, providing a means for PC Pentium mother board 105 to read and write the data bits of the invalid run-length register of the invalid symbol detector 201. The ISD 201 includes at least one register that is used to store and detect a specific run-length of channel bits in the bit stream. The ISD 201 invalid run-length mask register provides a means of selecting at least one channel bit run-length that will be detected in the EFM+ bit stream. The ISD 201 receives control signals from the ISA register address decode and control 211, that provide a means for the register selection, reading, and writing of the ISD 201 run-length mask register. The ISD 201 receives a clock signal from the sample size select 204, that is used to define the sample time period in which invalid symbols or selected channel bit run-lengths are detected and held. If an error is detected, the error flag output of the ISD 201 is asserted and held for the remainder of the sample time period. The error Rag output from the ISD 201 is used by the dual port memory port “A” controller dual port memory port “A” controller state machine 203 to determine if the data value in the error map array element for that sample period, representing the fixed linear and radial position, is to be incremented.

The table below defines the bits of an ISD 201 invalid run-length mask register:

ISD Invalid Run-Length Mask Register Bit Definitions

| Data bit | Invalid Run Length Detection Enabled | Read/Write |
|---|---|---|
| 0 | 1T | R/W |
| 1 | 2T | R/W |
| 2 | 12T | RIW |
| 3 | 13T | R/W |
| 4 | 15T+ | R/W |
| 5 | Not used | |
| 6 | Not used | |
| 7 | Not used | |

Note:
bit 4 selects invalid channel bit run-lengths that are 15T or greater in length.

The sample size select (SSS) circuit 204 includes a 16-bit binary counter that is incremented with each PLL clock cycle during a sample period. The SSS 204 also includes a 16-bit ISA register that can be written and read by software that holds the sample size limit in PLL clock cycles and a sample size flag output. The sample size flag is set and the 16-bit binary counter is cleared each time the same size limit is reached which starts the state machine and a dual port memory cycle.

The data bus 202 provides a means for data bit connection of the registers of the DVD error map ISA data interface 213 allowing ISA data bus 110 access to the PC Pentium motherboard 105. The data bus 202 consists of a plurality of data bits forming a bus providing read and write access to the DVD error map interface 109 internal registers. The selection of the register that is responsive to the data bus 202 is controlled by the ISA register address and control 211.

The dual port memory port “A” controller 203 performs the dual port “A” memory cycle using a state machine. The state machine receives the error flag signal from the ISD 201 and the sample size clock from the sample size select (SSS) 204. The sample size clock from the SSS 204 is used as a start signal for the state machine. When the state machine is started by the sample size clock, it reads the data value stored in the next element in the error map array. If an error has been detected during the sample period, the dual port memory port “A” controller state machine 203 increments the error map array element value that it read, and writes the incremented value back to the dual port memory 208 at the same error map array element location. The state machine is clocked using an oscillator. The frequency of the oscillator determines the speed of the dual port memory port “A” controller state machine 203, and therefore how fast it will perform its read, increment and write cycle to the dual port memory 208.

The SSS 204 is responsive to the data bus 202 providing a means to read and write the data bits of the sample size register of the SSS 204 using the decoding and control signals from the ISA register decode and control 211. The SSS 204 receives the PLL clock from the DVD ROM player 107. The SSS 204 is used as a means to determine the length of the sample period. During the sample period the bit stream will be checked for invalid symbols or selected channel bit run-lengths. The SSS 204 includes a register that may be written from the data bus 202 setting the number of PLL clock cycles per sample period. The SSS 204 also includes a binary counter that counts the number of PLL clock cycles in each sample. When the binary counter of the SSS 204 reaches the value that was stored in the sample size register the sample size flag output of the SSS 204 is asserted. The sample size flag output of the SSS 204 is used as an input to the dual port memory port “A” controller state machine 203 to start the read, increment and write cycle to the dual port memory 208.

In its accumulate mode, the sample size select (SSS) circuit 204 is loaded with a number indicative of the number of symbols to be examined during the traverse of a single localized area. The SSS circuit 204 can be either incremented or decremented to reach that number. When the number is reached, the SSS circuit 204 generates a control signal for application to the memory array 208 for addressing the next memory element associated with the next localized area. While the read beam is traversing that localized area, invalid or valid symbols can be selectively accumulated in the corresponding memory array element.

The SSS circuit 204 can be incremented or decremented by PLL signals from the data source. While each symbol is formed having a slight variation in the number of PLL signals per symbol it has been found that at most there is only a variation of one or two symbols per localized area in the data source, and that can be disregarded.

By counting the number of PLL signals coming from the data source before generating its control signal for selecting the next memory array storage element, the SSS circuit 204 is employed for selecting the linear length of the localized area. During the counting down or up mode of the SSS circuit 204, symbol errors are being accumulated into one memory element. When the SSS circuit 204 indicates that the linear length has been reached, the errors are accumulated in the next memory array element.

Means are provided for automatically accumulating symbol errors from adjacently positioned linear segments into the same memory array element. This is accomplished in part in combination with signals from the RCS circuit 205 and the control and status register 207.

As part of it's operation, the SSS circuit 204 is employed for defining the sample time period in which invalid symbols or selected channel bit run-length symbols are detected and or counted in an associated memory array element. A second function of the SSS circuit 204 is for determining the linear length of a data track positioned in a localized area. A further function of the SSS circuit 204 is for generating an output sample size select enable control signal when the predetermined number of channel bits has been counted. One of the uses of this sample size select enable control signal is to select another memory element to begin accumulating error signals from the next adjacently positioned localized area.

The table below defines the bits of a Sample Size Limit register:

Sample Size Limit Register Bit Definitions

| Data bit | Function/Description | Read/Write |
|---|---|---|
| 0 | Sample size limit bit 0 | R/W |
| 1 | Sample size limit bit 1 | R/W |
| 2 | Sample size limit bit 2 | R/W |
| 3 | Sample size limit bit 3 | R/W |
| 4 | Sample size limit bit 4 | R/W |
| 5 | Sample size limit bit 5 | R/W |
| 6 | Sample size limit bit 6 | R/W |
| 7 | Sample size limit bit 7 | R/W |
| 8 | Sample size limit bit 8 | R/W |
| 9 | Sample size limit bit 9 | R/W |
| 10 | Sample size limit bit 10 | R/W |
| 11 | Sample size limit bit 11 | R/W |
| 12 | Sample size limit bit 12 | R/W |
| 13 | Sample size limit bit 13 | R/W |
| 14 | Sample size limit bit 14 | R/W |
| 15 | Sample size limit bit 15 | R/W |

The state machine 203 is clocked with oscillator 207. When the sample size flag is set the state machine 203 is started. The dual port memory port “A” address generator 206 increments the dual port “A” memory address pointing to the next location in the error map array. The dual port “A” memory 208 location is read and the value is stored in a 16-bit parallel-loaded binary counter in the state machine 203. The value stored in the binary counter will be incremented if the invalid symbol flag was set by the ISD 201. The value stored in the binary counter will then be written back to the same dual port “A” memory location. The invalid symbol flag and sample size flag are cleared after the dual port memory location is written with the stored value. The state machine that reads and writes the dual port memory is stopped until the next sample size flag is set.

Next, the tach bit input from the DVD drive 107 is checked. If the tach bit is not set the state machine waits for the next sample size flag. When the tach bit is set indicates that a complete rotation of the disc has occurred. When the tach bit is set the dual port “A” memory address will be set back to first location of the error map array and the tach bit will be cleared. The rotation count select RCS 205 circuit includes an 8-bit binary counter that is incremented each time the tach bit is set. The RCS 205 also includes an 8-bit rotation limit register and a bit that is read from the control and status register (CSR) 207 indicating that the error map array is done. The RCS 205 rotation limit register can be written or read by software on the ISA bus 110. The rotation limit determines how many rotations of the disc will occur before the array done flag is set, and the buffer where the error map array is stored switches. The table below defines the bits of the rotation limit register of the RCS 205:

The rotation count select (RCS) 205 is responsive to the data bus 202, providing a means to read and write the data bits of the rotation count limit register of the RCS 205, using the decode and control signals from the ISA register decode and control 211. The RCS 205 receives the tach signal from the DVD ROM drive 107. The RCS 205 includes a binary counter that is incremented by the tach signal output from the DVD ROM drive 107. The binary counter is used to count the number of rotations of the disc representing the radial resolution of error map array. The rotation count limit flag output of the RCS 205 is asserted when the binary counter reaches the value stored in the rotation count limit register. The rotation count limit flag output of the RCS 205 is used by the dual port “A” address generator 206 to determine when the buffer storing the current error map array in the dual port memory 208 is switched to the next element.

In operation, the rotation count select circuit (RCS) 205 is loaded with a number indicating the number of tracks that will be included in a localized area from the data source. The tracks could be sourced relative to a picture from a television signal and in such a case would be referenced to horizontal scan lines. When the RCS circuit 205 is incremented to the number of tracks in a localized area, the once around tack signal is used to decrement this number to zero. With reference to a television signal, the horizontal sync signal could be used for this purpose. At zero or any other designated number, the RCS circuit 205 generates a signal for incrementing the memory array 208 to its next element for storing errors from the adjacent area of the optical disc or other data source. While the RCS circuit 205 is decrementing toward zero, symbol errors from the data source, as detected in the ISD circuit 201 are being accumulated in the currently addressed position of the memory array 208. As the storage element in the array 208 was chosen to be an eight-bit counter, the number of errors on the chosen number of tracks is being counted in this counter.

As described, the number in the RCS 205 can be either incremented or decremented. Therefore, the next memory array element is selected whenever the count reaches the number selected by the designer. Now, the errors are being accumulated in a second memory array element.

Briefly, the rotation count select circuit (RCS) 205 is responsive to each tach signal received from the data source for indicating the presence of another track in the selected size of the localized area from the source. The errors detected during this time are summed into the addressed memory array element. The RCS circuit 205 is further employed for generating a control signal for application to the memory array for providing at least one memory array input control signal for selecting the next successive positioned memory array element as the storage location for errors detected in the next corresponding localized area.

The table below defines the bits of the rotation limit register of the RCS 205:

Rotation Limit Register Bit Definitions

| Data bit | Function/Description | Read/Write |
|---|---|---|
| 0 | Rotation limit bit 0 | R/W |
| 1 | Rotation limit bit 1 | R/W |
| 2 | Rotation limit bit 2 | R/W |
| 3 | Rotation limit bit 3 | R/W |
| 4 | Rotation limit bit 4 | R/W |
| 5 | Rotation limit bit 5 | R/W |
| 6 | Rotation limit bit 6 | R/W |
| 7 | Rotation limit bit 7 | R/W |

The dual port memory address “A” generator 206 receives the sample size limit flag from the SSS 204 and the rotation count limit flag from the RCS 205. The dual port memory address “A” generator 206 controls the port “A” address to the dual port memory port 208. The dual port memory port “A” address 206 is used to select the error map array element that may be read and written by the dual port memory port “A” controller state machine 203. The dual port memory port “A” address 206 is reset to the start or first element in the error map array by the assertion of the rotation count limit flag output of the RCS 205. The dual port memory port “A” address 206 is incremented each time the sample size limit flag is asserted for selecting the next memory element location in the array. The dual port memory 208 port “A” address bits are connected as inputs to the control and status register (CSR) 207.

The CSR 207 is responsive to the data bus 202 providing a means to read the data bits of the CSR using the decoding and control signals from the ISA register decode and control 211. The CSR 207 receives the address bits from the dual port memory port “A” address generator 206. The address bits determine the size or last location of the error map array that is stored in the dual port memory 208. The CSR 207 receives the rotation count limit output from the RCS 205. The rotation count limit signal is used to set the error map array done bit in the CSR 207 register. The table below defines the bits of the CSR 207:

CSR Bit Definitions

| Data bit | Function/Description | Read/Write |
|---|---|---|
| 0 | Last error map array element address bit 0 | Read only |
| 1 | Last error map array element address bit 1 | Read only |
| 2 | Last error map array element address bit 2 | Read only |
| 3 | Last error map array element address bit 3 | Read only |
| 4 | Last error map array element address bit 4 | Read only |
| 5 | Last error map array element address bit 5 | Read only |
| 6 | Last error map array element address bit 6 | Read only |
| 7 | Last error map array element address bit 7 | Read only |
| 8 | Last error map array element address bit 8 | Read only |
| 9 | Last error map array element address bit 9 | Read only |
| 10 | Last error map array element address bit 10 | Read only |
| 11 | Last error map array element address bit 11 | Read only |
| 12 | Last error map array element address bit 12 | Read only |
| 13 | Buffer valid bit | Read only |
| 14 | Error map array done bit | Read only |
| 15 | Not used | |

Note:
CSR bit 14 is cleared automatically by hardware after each read of the CSR.

The dual port memory 208 can be implemented using a single LSI such as the CY7C025. The CY7C025 is an 8192 location by 16-bit dual port memory manufactured by Cypress Semiconductor. The CY7C025 allows independent access of a common semiconductor static memory bank from two separate address, data and control ports. The dual port memory 208 is used to store the error map array. The elements of the error map array are made up of 16-bit words of the dual port memory 208. The dual port memory 208 receives port “A” control from the dual port memory port “A” controller state machine 203 and port “A” address from the dual port memory port “A” address generator 206. The address and control of Port “B” of the dual port memory 208 is supplied by the dual port memory port “B” interface 209. Port “B” data of the dual port memory 208 is responsive to the data bus 202. The data bus 202 providing a means to read and write the data bits of the dual port memory 208 from the ISA data bus interface 213.

In review, at least one sample size select detector circuit 204 is responsive to the data bus and the phase lock loop clocking signal for identifying at least one invalid symbol form the digitally encoded bit pattern. A PLL signal is employed for establishing the start and end time periods in the selected group of bits identified in the bit stream pattern. A serial register is employed for storing the selected group of bits identified in the bit stream pattern. An output signal from the serial register is employed for indicating that the selected group of bits has been identified in the bit stream pattern. A sample size clocking means is employed for identifying the actual bit pattern in the sample.

The dual port memory port “B” interface 209 provides the address and control signals to read and write the dual port memory 208. The dual port memory port “B” interface 209 includes a parallel loaded 13-bit binary counter that can be written and read from the data bus 202 and down stream by the PC ISA bus interface 213. The 13-bit counter outputs are used as the dual port memory port “B” address of the dual port memory 208. The dual port memory 208 may written and read from a single address decoded by the ISA register address decoding and control 211. The dual port memory port “B” 13 bit counter is incremented by the dual port memory port “B” interface 209 each time the dual port memory 208 is written or read from the PC ISA bus interface 213. By incrementing the 13-bit counter, the sequential locations of the dual port memory 208 can be written or read from the PC ISA bus 110 without re-writing the 13 bit counter parallel loaded address value.

The DVD player interface connector 210, providing a means to receive wires or cable containing the EFM+, PLL clock, and tach signals from the DVD ROM drive 107.

The ISA register address decode and control 211, providing a means to decode the ISA address input from the ISA address and control interface 212, creates separate register decode signals for each of the DVD error mapping interface 109 registers. The ISA register decode and control 211 also receives control signals from the ISA address and control interface 212, that are used to create the DVD error mapping interface 109 register read and write signal.

The ISA address and control interface 212, providing a means to interface the DVD error mapping interface 109 to the PC ISA bus 110. The ISA address and control interface 212 can be implemented using an integrated circuit such as the SN74LS240 octal buffer, manufactured by Texas Instruments.

The ISA data bus interface 213, providing a means to interface the data bus 202 to the ISA data bus 215. The ISA data bus interface 213 can be implemented using an integrated circuit such as the SN74LS245 octal bus transceiver, manufactured by Texas Instruments. The octal bus transceivers in the ISA data bus interface 213 are controlled by the board select signal and read/write (R/W) signal from the ISA register address decode and control 211.

The PC ISA bus 110 is made up of ISA control bus signals 216, ISA data bus signals 215, and ISA address bus signals 214. The ISA bus 110 provides a means for the PC Pentium motherboard 105 to access the registers on the DVD error mapping interface 109.

The inventive process of creating a DVD digital error map begins by inserting a DVD disc to be error mapped in to the DVD drive 107. The DVD disc is played and the ISD 201 circuit monitors the EFM+ bit stream, received on the DVD player interface connector 210, for specific channel bit run-lengths in the run-length limited EFM+ bit stream, generated by reading the DVD media.

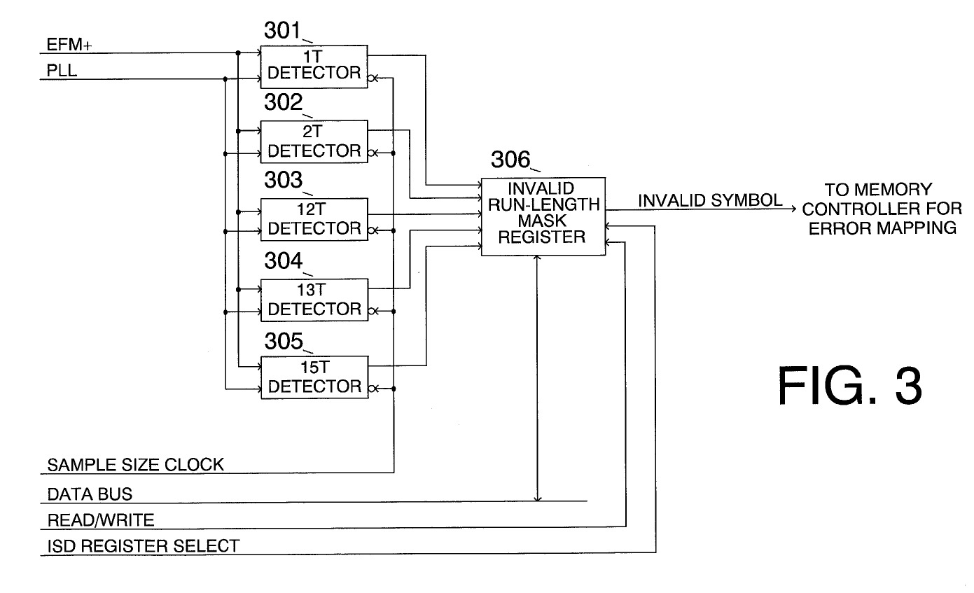

With reference to FIG. 3, the ISD 201 is shown in more detail. The ISD 201 is made up of at least one run-length detector as shown in the separate circuits FIG. 3, 301 through 305, that detect specific channel bit run-lengths in the EFM+ signal.

The 1T detector 301 receives the EFM+ signal and PLL clock from the DVD ROM drive 107. The sample size clock from SSS 204 is used by the 1T detector 301 to determine the start and stop period of each sample. The 1T detector 301 detects the occurrence of 1T run-lengths in the EFM+ bit stream. The PLL clock defines the start and stop period of time representing a single channel bit in the EFM+ encoded data bit stream. The EFM+ serial stream consists of channel bits grouped in to channel bit patterns forming EFM+ symbols. The 1T detector 301 output is asserted when a 1T has been detected in the EFM+ bit stream during the sample period. The sample size clock is used to clear the 1T detector output and latch the 1T detector 301 output into the invalid run-length mask register 306.

The 2T detector 302 receives the EFM+ signal and PLL clock from the DVD ROM drive 107. The sample size clock from SSS 204 is used by the 2T detector 302 to determine the start and stop period of each sample. The 2T detector 302 detects the occurrence of 2T run-lengths in the EFM+ bit stream. The PLL clock defines the start and stop period of time representing a single channel bit in the EFM+ encoded data bit stream The EFM+ serial stream consists of channel bits grouped in to channel bit patterns forming EFM+ symbols. The 2T detector 302 output is asserted when a 2T has been detected in the EFM+ bit stream during a sample period. The sample size clock is used to clear the 2T detector output and latch the 2T detector output 302 into the invalid run-length mask register 306.

The 12T detector 303 receives the EFM+ signal and PLL clock from the DVD ROM drive 107. The sample size clock from SSS 204 is used by the 12T 303 detector to determine the start and stop period of each sample. The 12T detector 303 detects the occurrence of 12T run-lengths in the EFM+ bit stream. The PLL clock defines the start and stop period of time representing a single channel bit in the EFM+ encoded data bit stream The EFM+ serial stream consists of channel bits grouped in to channel bit patterns forming EFM+ symbols. The 12T detector 303 output is asserted when a 12T has been detected in the EFM+ bit stream during a sample period. The sample size clock is used to clear the 12T detector output and latch the 12T detector output 303 into the invalid run-length mask register 306.

The 13T detector 304 receives the EFM+ signal and PLL clock from the DVD ROM drive 107. The sample size clock from SSS 204 is used by the 13T detector 304 to determine the start and stop period of each sample. The 13T detector 304 detects the occurrence of 13T run-lengths in the EFM+ bit stream The PLL clock defines the start and stop period of time representing a single channel bit in the EFM+ encoded data bit stream. The EFM+ serial stream consists of channel bits grouped in to channel bit patterns forming EFM+ symbols. The 13T detector 304 output is asserted when a 13T has been detected in the EFM+ bit stream during a sample period. The sample size clock is used to clear the 13T detector output and latch the 13T detector output 304 into the invalid run-length mask register 306.

The 15T detector 305 receives the EFM+ signal and PLL clock from the DVD ROM drive 107. The sample size clock from SSS 204 is used by the 15T detector 305 to determine the start and stop period of each sample. The 15T detector 305 detects the occurrence of 15T run-lengths or longer in the EFM+ bit stream. The PLL clock defines the start and stop period of time representing a single channel bit in the EFM+ encoded data bit stream. The EFM+ serial stream consists of channel bits grouped in to channel bit patterns forming EFM+ symbols. The 15T detector 305 output is asserted when a 15T has been detected in the EFM+ bit stream during a sample period. The sample size clock is used to clear the 15T detector output and latch the 15T detector 305 output into the invalid run-length mask register 306.

The invalid run-length mask register 306 receives the output of the 1T detector 301, 2T detector 302, 12T detector 303, 13T detector 304 and the 15T detector 305. The invalid run-length mask register 306 is connected to the data bus providing a means for reading and writing a register controlling which run-lengths will set the invalid symbol output. The invalid symbol output of the invalid run-length detector 306 is received by the dual port memory port “A” controller state machine 203 to determine if the error map array element value for that sample is incremented. The invalid run-length mask register 306 receives the register select and read and write control signals from the ISA register address decode and control register 211 providing a means to read and write the run-length mask register.

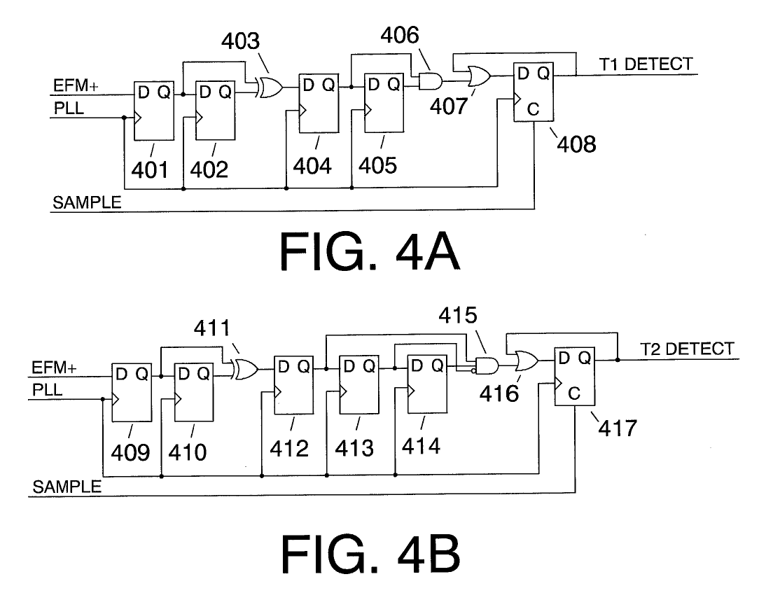

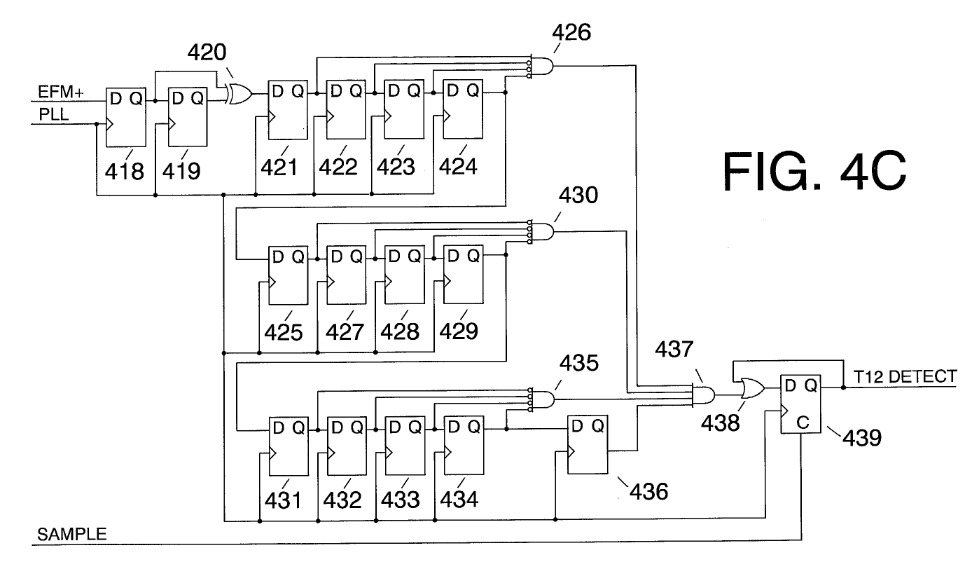

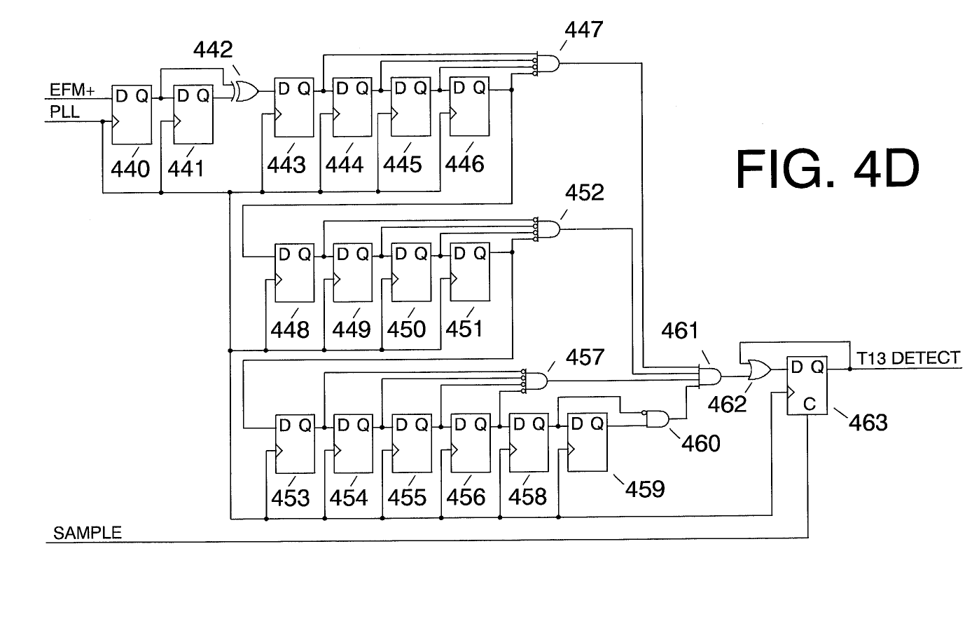

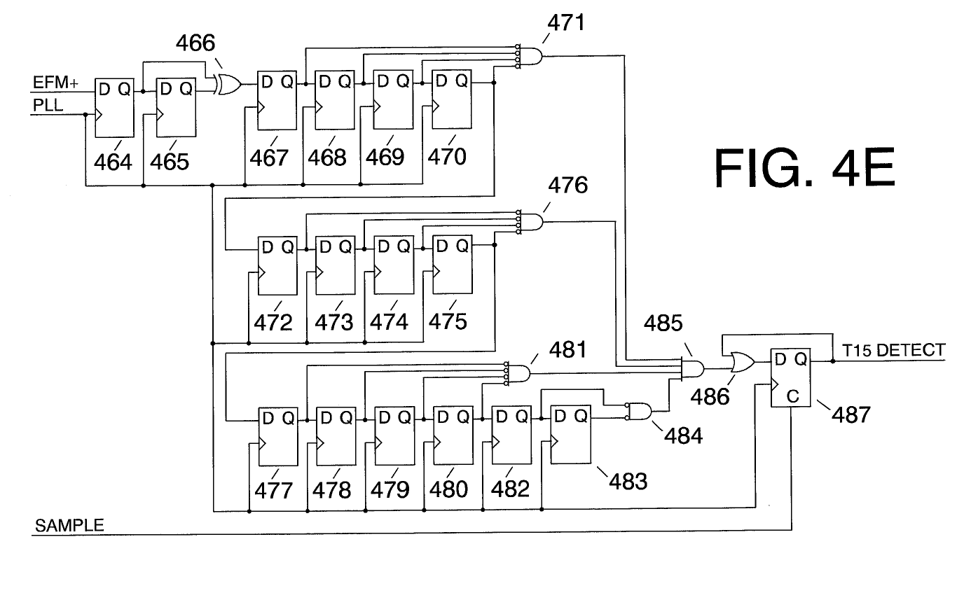

With reference to FIG. 4a, a 1T detector is described in detail. The state of the EFM+ input signal is latched on the rising edge of the PLL clock into the flip-flop 401 of the 1T detector circuit 301. The output of flip-flop 401 is latched into flip-flop 402 with the rising edge of the PLL clock. The exclusive OR gate 403 is connected to output of flip-flops 401 and 402, and is used to determine when the state of flip-flops 401 and 402 outputs are not equal, indicating a transition in the EFM+ signal. The output of the exclusive OR gate 403 is latched on the rising edge of the PLL clock into the flip-flop 404. The output of flip-flop 404 is latched into flip-flop 405 on the rising edge of the PLL clock. The two inputs of the AND gate 406 are connected to the output of flip-flops 404 and 405, and are used to detect when the output of flip-flops 404 and 405 are both asserted indicating the detection of a 1T. The output of the AND gate 406 is used as one of the inputs to the two input OR gate 407. The output of the OR gate 407 is latched into flip-flop 408 using the rising edge of the PLL clock. The output of the flip-flop 408 is used as the second input of the OR gate 407 forming a hold circuit that will hold a detected 1T until the flip-flop 408 is cleared by the assertion of the sample signal.

With reference to FIG. 4b a 2T detector is described in detail. The state of the EFM+ input signal is latched on the rising edge of the PLL clock into the flip-flop 409 of the 2T-detector circuit 302. The output of flip-flop 409 is latched into flip-flop 410 with the rising edge of the PLL clock. The exclusive OR gate 411 is connected to output of flip-flops 409 and 410, and is used to determine when the state of flip-flops 409 and 410 outputs are not equal, indicating a transition in the EFM+ signal. The output of the exclusive OR gate 411 is latched on the rising edge of the PLL clock into the flip-flop 412. The output of flip-flop 412 is latched into flip-flop 413 on the rising edge of the PLL clock. The output of flip-flop 413 is latched into flip-flop 414 on the rising edge of the PLL clock. The three inputs of the AND gate 415 are connected to the output of flip-flops 412, 413 and 414, and are used to detect when the output of flip-flops 412 and 414 are both asserted and flip-flop 413 is negated indicating the detection of a 2T. The output of the AND gate 415 is used as one of the inputs to the two input OR gate 416. The output of the OR gate 416 is latched into flip-flop 417 using the rising edge of the PLL clock. The output of the flip-flop 417 is used as the second input of the OR gate 416 forming a hold circuit that will hold a detected 2T until the flip-flop 417 is cleared by the assertion of the sample signal.

With reference to FIG. 4c, a 12T detector is described in detail. The state of the EFM+ input signal is latched on the rising edge of the PLL clock into the flip-flop 418 of the 12T-detector circuit 303. The output of flip-flop 418 is latched into flip-flop 419 with the rising edge of the PLL clock. The exclusive OR gate 420 is connected to output of flip-flops 418 and 419, and is used to determine when the state of flip-flops 418 and 419 outputs are not equal, indicating a transition in the EFM+ signal. The output of the exclusive OR gate 420 is latched on the rising edge of the PLL clock into the flip-flop 421. The output of flip-flop 421 is latched into flip-flop 422 on the rising edge of the PLL clock. The output of flip-flop 422 is latched into flip-flop 423 on the rising edge of the PLL clock. The output of flip-flop 423 is latched into flip-flop 424 on the rising edge of the PLL clock. The output of flip-flop 424 is latched into flip-flop 425 on the rising edge of the PLL clock. The output of flip-flop 425 is latched into flip-flop 427 on the rising edge of the PLL clock. The output of flip-flop 427 is latched into flip-flop 428 on the rising edge of the PLL clock. The output of flip-flop 428 is latched into flip-flop 429 on the rising edge of the PLL clock. The output of flip-flop 429 is latched into flip-flop 431 on the rising edge of the PLL clock. The output of flip-flop 431 is latched into flip-flop 432 on the rising edge of the PLL clock. The output of flip-flop 432 is latched into flip-flop 433 on the rising edge of the PLL clock. The output of flip-flop 433 is latched into flip-flop 434 on the rising edge of the PLL clock. The output of flip-flop 434 is latched into flip-flop 436 on the rising edge of the PLL clock. The four inputs of the AND gate 426 are connected to the output of flip-flops 421, 422, 423 and 424 and are used to detect when the output of flip-flops 421 is asserted and flip-flop 422, 423 and 424 are negated. The four inputs of the AND gate 430 are connected to the output of flip-flops 425, 427, 428 and 429 and are used to detect when the output of flip-flops 425, 427, 428 and 429 are negated. The four inputs of the AND gate 435 are connected to the output of flip-flops 431, 432, 433 and 434 and are used to detect when the output of flip-flops 431, 432,433, and 434 are negated. The four inputs of the AND gate 437 are connected to the output of AND gates 426, 430,435, and flip-flop 436, and are used to detect when the output of AND gates 426, 430, 435 and flip-flop 436 are asserted indicating the detection of a 12T. The output of the AND gate 437 is used as one of the inputs to the two input OR gate 438. The output of the OR gate 438 is latched into flip-flop 439 using the rising edge of the PLL clock. The output of the flip-flop 439 is used as the second input of the OR gate 438 forming a hold circuit that will hold a detected 12T until the flip-flop 439 is cleared by the assertion of the sample signal.

With reference to FIG. 4d, a 13T detector is described in detail. The state of the EFM+ input signal is latched on the rising edge of the PLL clock into the flip-flop 440 of the 13T-detector circuit 304. The output of flip-flop 440 is latched into flip-flop 441 with the rising edge of the PLL clock. The exclusive OR gate 442 is connected to output of flip-flops 440 and 441, and is used to determine when the state of flip-flops 440 and 441 outputs are not equal, indicating a transition in the EFM+ signal. The output of the exclusive OR gate 442 is latched on the rising edge of the PLL clock into the flip-flop 443. The output of flip-flop 443 is latched into flip-flop 444 on the rising edge of the PLL clock. The output of flip-flop 444 is latched into flip-flop 445 on the rising edge of the PLL clock. The output of flip-flop 445 is latched into flip-flop 446 on the rising edge of the PLL clock. The output of flip-flop 446 is latched into flip-flop 448 on the rising edge of the PLL clock. The output of flip-flop 448 is latched into flip-flop 449 on the rising edge of the PLL clock. The output of flip-flop 449 is latched into flip-flop 450 on the rising edge of the PLL clock. The output of flip-flop 450 is latched into flip-flop 451 on the rising edge of the PLL clock. The output of flip-flop 451 is latched into flip-flop 453 on the rising edge of the PLL clock. The output of flip-flop 453 is latched into flip-flop 454 on the rising edge of the PLL clock. The output of flip-flop 454 is latched into flip-flop 455 on the rising edge of the PLL clock. The output of flip-flop 455 is latched into flip-flop 456 on the rising edge of the PLL clock. The output of flip-flop 456 is latched into flip-flop 458 on the rising edge of the PLL clock. The output of flip-flop 458 is latched into flip-flop 459 on the rising edge of the PLL clock. The four inputs of the AND gate 447 are connected to the output of flip-flops 443, 444, 445 and 446, and are used to detect when the output of flip-flops 443 is asserted and flip-flop 444, 445 and 446 are negated. The four inputs of the AND gate 452 are connected to the output of flip-flops 448, 449, 450 and 451, and are used to detect when the output of flip-flops 448, 449, 450 and 451 are negated. The four inputs of the AND gate 457 are connected to the output of flip-flops 453, 454, 455 and 456, and are used to detect when the output of flip-flops 453, 454, 455 and 456 are negated. The two inputs of AND gate 460 are connected to the output of flip-flops 458 and 459 and used to detect when the output of flip-flop 458 is negated and flip-flop 459 is asserted. The four inputs of the AND gate 461 are connected to the output of AND gates 447, 452, 457 and 460, and are used to detect when the output of AND gates 447, 452, 457 and 460 are asserted indicating the detection of a 13T. The output of the AND gate 461 is used as one of the inputs to the two input OR gate 462. The output of the OR gate 462 is latched into flip-flop 463 using the rising edge of the PLL clock. The output of the flip-flop 463 is used as the second input of the OR gate 462 forming a hold circuit that will hold a detected 13T until the flip-flop 463 is cleared by the assertion of the sample signal.

With reference to FIG. 4e, a 15T+ detector is described in detail. The state of the EFM+ input signal is latched on the rising edge of the PLL clock into the flip-flop 464 of the 15T+ detector circuit 305. The output of flip-flop 464 is latched into flip-flop 465 with the rising edge of the PLL clock. The exclusive OR gate 466 is connected to output of flip-flops 464 and 465, and is used to determine when the state of flip-flops 464 and 465 outputs are not equal indicating a transition in the EFM+ signal. The output of the exclusive OR gate 466 is latched on the rising edge of the PLL clock into the flip-flop 467. The output of flip-flop 467 is latched into flip-flop 468 on the rising edge of the PLL clock. The output of flip-flop 468 is latched into flip-flop 469 on the rising edge of the PLL clock. The output of flip-flop 469 is latched into flip-flop 470 on the rising edge of the PLL clock. The output of flip-flop 470 is latched into flip-flop 472 on the rising edge of the PLL clock. The output of flip-flop 472 is latched into flip-flop 473 on the rising edge of the PLL clock. The output of flip-flop 473 is latched into flip-flop 474 on the rising edge of the PLL clock. The output of flip-flop 474 is latched into flip-flop 475 on the rising edge of the PLL clock. The output of flip-flop 475 is latched into flip-flop 477 on the rising edge of the PLL clock. The output of flip-flop 477 is latched into flip-flop 478 on the rising edge of the PLL clock. The output of flip-flop 478 is latched into flip-flop 479 on the rising edge of the PLL clock. The output of flip-flop 479 is latched into flip-flop 480 on the rising edge of the PLL clock. The output of flip-flop 480 is latched into flip-flop 482 on the rising edge of the PLL clock. The output of flip-flop 482 is latched into flip-flop 483 on the rising edge of the PLL clock. The four inputs of the AND gate 471 are connected to the output of flip-flops 467, 468, 469 and 470, and are used to detect when the output of flip-flops 467, 468, 469 and 470 are negated. The four inputs of the AND gate 476 are connected to the output of flip-flops 472, 473, 474 and 475, and are used to detect when the output of flip-flops 472, 473, 474 and 475 are negated. The four inputs of the AND gate 481 are connected to the output of flip-flops 477, 478, 479 and 480, and are used to detect when the output of flip-flops 477, 478, 479 and 480 are negated. The two inputs of AND gate 484 are connected to the output of flip-flops 482 and 483, and used to detect when the output of flip-flop 482 and 483 are negated. The four inputs of the AND gate 485 are connected to the output of AND gates 471, 476, 481 and 484, and are used to detect when the output of AND gates 471, 476, 481 and 484 are asserted indicating the detection of a 15T or longer run-length. The output of the AND gate 485 is used as one of the inputs to the two input OR gate 486. The output of the OR gate 486 is latched into flip-flop 487 using the rising edge of the PLL clock. The output of the flip-flop 487 is used as the second input of the OR gate 486 forming a hold circuit that will hold a detected 15T+ until the flip-flop 487 is cleared by the assertion of the sample signal.

It is important to note that the invalid run-length detectors detailed in FIG. 4 a through FIG. 4e are examples to show how specific channel bit run-lengths can be detected discreetly using digital logic circuits. The digital logic of the invalid run-length detectors can be optimized by removing redundant circuits. The specific run-length detectors can also be implemented in many different ways such as using a binary counter in place of the shift register, made up of flip-flops, to count the number of PLL clock cycles in each specific run-length. The specific run-length circuits can also be changed such that the channel bit run-length is detected in NRZI encoded data rather than detecting channel bit run-lengths in NRZ encoded data as shown in FIG. 4. To detect run-lengths in NRZI encoded data the state of the serial NRZI encoded data is measured in PLL clock cycles. Detecting channel bit run-lengths in NRZI encoded data allows the determination of the source (pit or land) of the specific channel bit run-length. It should also be pointed out that the run-lengths that can be detected are not limited to the examples shown in FIG. 4. The invalid run-length detector can be changed to detect any specific run-length by changing the number of flip-flop stages in the shift register that receives the serial signal. Changing the run-lengths detected allow the inventive method to be applied to different data formats or systems that do use digital data formats to store information.

Detecting invalid symbols can be implemented using a look-up-table versus invalid run-length detectors. The advantage of using a look-up-table is that invalid symbols that do not contain invalid channel bit run-lengths can also be detected and mapped. The serial data signal input is latched into a shift register and the parallel output of the shift register is used as the address to a look-up-table implemented with a memory means where a bit or bits indicating whether a symbol is valid are stored.

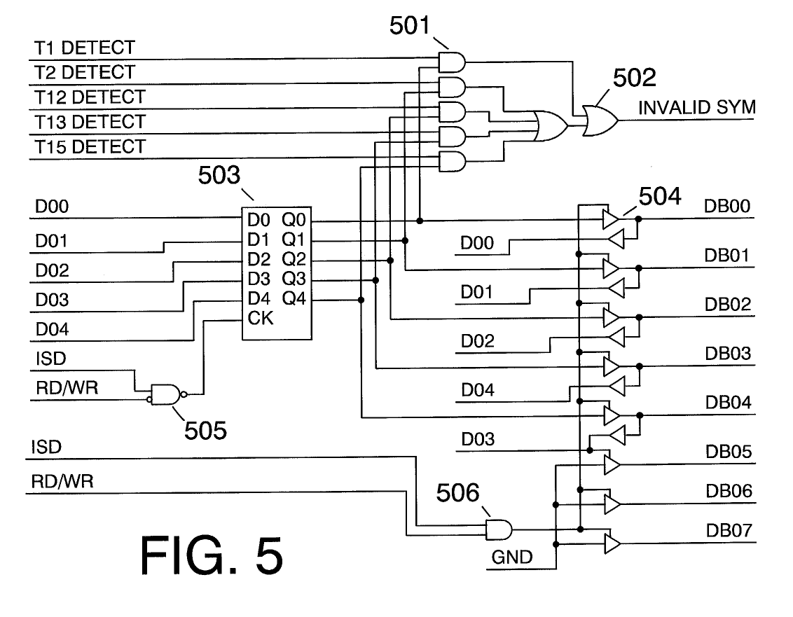

With reference to FIG. 5 an invalid run-length mask register is described in detail. Data bits 0 through 4 inputs from the data bus transceiver 504 are written with the rising edge of the output of the NAND gate 505 to the 5-bit latch 503 creating the run-length mask. The AND gate 506 enables the output of the data bus transceiver, allowing the value stored in the 5-bit latch to be read on to the data bus. The five outputs of the 5-bit latch 503 are used as one input of each of the five two input AND gates 501. The other input for the AND gates 501 are the 1T, 2T, 12T, 13T and 15T+ detect signals. The outputs of the 5-bit latch 503 act as enables for each of the invalid run-length detect signals. The outputs of the five AND gates 501 are inputs to a five input OR gate 502. The output of the 5-input OR gate 502 is the invalid symbol signal that is used by the dual port memory port “A” controller state machine 203 to determine when the corresponding error map array element value should be incremented. The corresponding bit must be set in the invalid run-length mask register 503 to enable the detection of each specific channel bit run-length during each sample period.

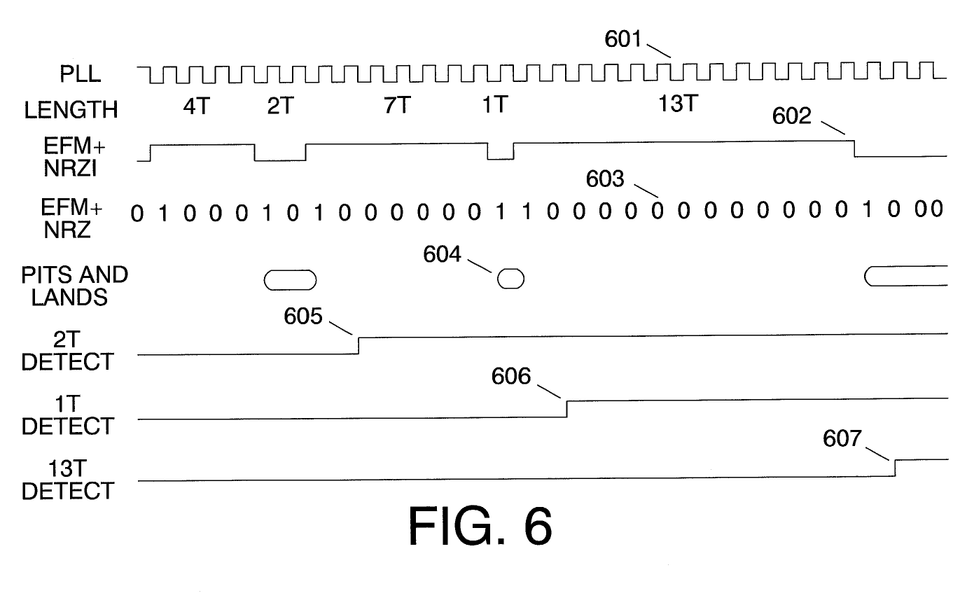

With reference to FIG. 6, 1T, 2T, and 13T invalid run-length detect example. The DVD ROM drive 107 provides the source of the PLL clock signal 601 that determines the start and stop period consisting of a single channel bit time in the EFM+ bit stream. The DVD ROM drive 107 is also the source of the EFM+ NRZI signal 602. The EFM+ NRZI signal is a bit stream consisting of a plurality of single bits grouped into 16-channel bit patterns forming EFM+ symbols. In non-return-to-zero encoding (NRZ) 603 format, transitions in the EFM+ signal are decoded as ones, and PLL clock cycles without a transition are decoded as zeros. Pits 604 relate to the negated state of the EFM+ NRZI 602 signal and lands relate to the asserted state of the EFM+ NRZI 602 signal. A serial 3-bit pattern of “101” in EFM+ NRZ encoded data is detected as a 2T, indicated by the asserted state of the 2T detect 605. The assertion of the 2T detect 605 has a propagation delay of two PLL clock periods caused by the 2T detector 302. A serial 2-bit pattern of “11” in EFM+ NRZ encoded data is detected as a 1T indicated by the assertion of the 1T detect 606. The assertion of the 1T detect 606 has a propagation delay of two PLL clock periods caused by the 1T detector 301. A serial 14-bit pattern of “10000000000001” in EFM+ NRZ encoded data is detected as a 13T indicated by the asserted state of the 13T detect 607. The assertion of the 13T detect 607 has a propagation delay of two PLL clock periods caused by the 13T detector 304. The 1T 606, 2T 605 and 13T 607 detect signals will be held if asserted until the start of the next sample time. The 1T 606, 2T 605 and 13T 607 detect are received by the invalid run-length mask register 306.

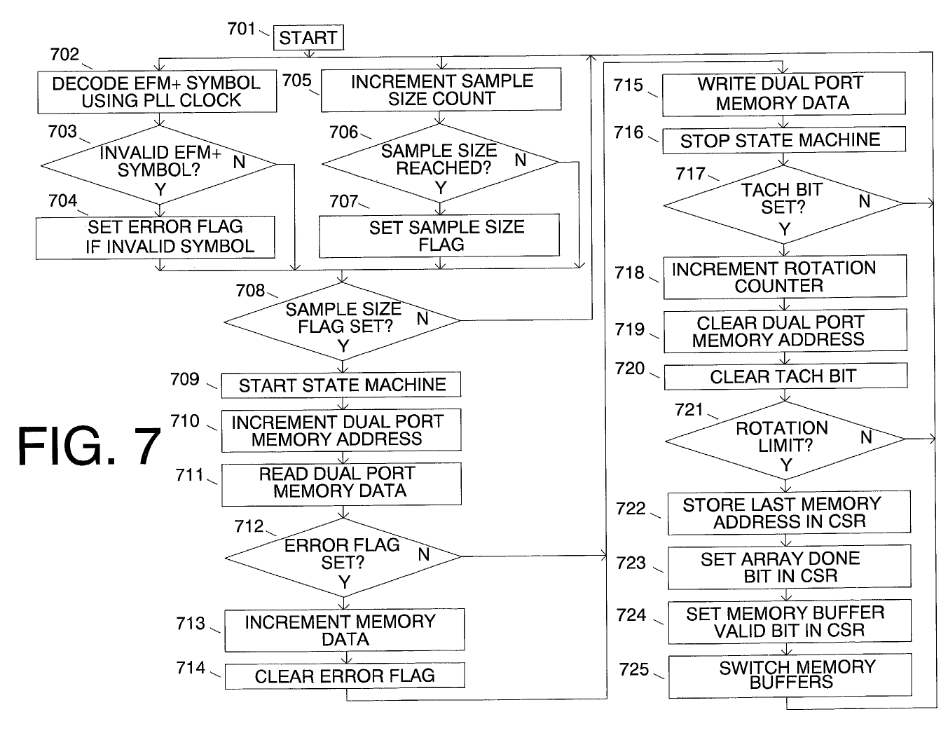

With reference to FIG. 7, the inventive hardware process to create an error map array is expressed in a flow chart. The hardware process of creating an error array begins at step 701, by decoding an EFM+ symbol using the PLL clock, at step 702, and incrementing the sample size counter, at step 705. The EFM+ symbol is checked to see if it is an invalid symbol, at step 703, and the sample size limit is checked, at step 706. If the error flag is set if an invalid symbol is detected, at step 704. The sample size flag is set the sample size limit is reached, at step 707. If the sample size flag is not set return to start, step 701. The state machine is started, at step 709, if the sample size flag is set, at step 708. The dual port memory address is incremented, at step 710, pointing to the next location in the error map array. The dual port memory data at that location is read, at step 711. If the error flag is set, at step 712, increment the value read from the dual port memory, at step 713, and clear the error flag, at step 714. If the error flag is not set, at step 712, skip incrementing the value read. Write the data value back to the dual port memory, at step 715, and stop state machine, at step 716. If the tach bit is not set, at step 717, return to start, step 701. If the tach bit is set, at step 717, increment the rotation counter at step 718, clear the dual port memory address at step 719 so it points to the starting location of the error map array and clear the tach bit at step 720. Check the if the rotation limit has been reached, at step 721. If the rotation limit has not been reached return to start, step 701. If the rotation limit has been reached store the last dual port memory address (end of the array) in the CSR register, at step 722. Set the array done bit in CSR, at step 723, set the buffer valid bit in the CSR, at step 724, and switches memory buffers, at step 725. Return to start, step 701.

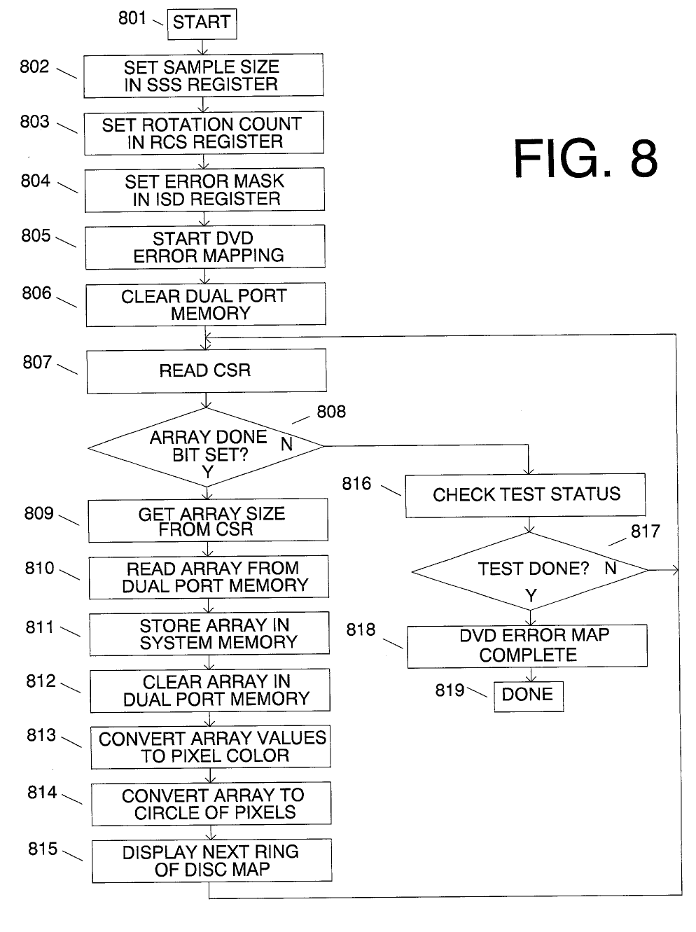

With reference to FIG. 8, the inventive software process to create a DVD error map using the DVD error mapping ISA interface is expressed in a flow chart. The software program process of creating a DVD error map starts, at step 801, with the initialization or setting of the sample size register, at step 802, on the DVD error mapping ISA interface. The value written to the sample size register determines the length of each sample in PLL clock cycles, therefore controlling the linear resolution of the resulting error map. The rotation count limit is written to the rotation count select register, at step 803. The rotation count controls the radial resolution of the resulting error map by setting the number of rotations that will be stored in each error map array. The error mask or invalid run-length mask is set, at step 804. The error mask determines which invalid channel bit run-lengths are mapped as errors. Once the DVD error mapping ISA interface registers have been set the process of actually mapping digital errors can begin, at step 805. The error mapping process begins by clearing the dual port memory, at step 806, on the DVD error mapping ISA interface. The CSR of the DVD error-mapping interface is read, at step 807. If the array done bit is not set, at step 808, check test status, at step 816. If test done, at step 817, DVD error map complete at step 818, and map done, at step 819. If test not done, at step 817, return to reading CSR, at step 807. If the array done bit is set at step 808, in the value read from the CSR 807, the error map array size can be determined. Get array size, at step 809. The error map array is read from the DVD error map ISA interface dual port memory, at step 810. The array is read and stored in system memory, at step 811. The DVD error map ISA interface dual port memory array storage is then cleared, at step 812. The stored error map array element values are converted to values that will represent a pixel color, at step 813, when displayed. The array of pixel colors is next converted into a circular band of pixels, at step 814 and displayed as the next ring of pixels in the DVD error map, at step 815. The process of creating a DVD error map with rings of pixels added to the displayed DVD error map until the end of the test is reached, at step 819.

The preferred embodiment details the invalid run-length detectors as detecting invalid channel bit run-lengths in the NRZ encoded data. An alternate embodiment of the invention would detect invalid channel bit run-lengths in NRZI encoded data. The NRZI encoded data is directly related to the pits and lands of the optical media, therefore permitting the determination of whether the invalid channel bit run-length was caused by an invalid channel bit length derived from a pit or land. The alternate embodiment would detect invalid channel bit run-lengths in the NRZI encoded data before decoding the NRZI data into NRZ data The preferred embodiment details a DVD error mapping circuit and method. The circuit and method described may be used on other forms of optical media with different formats such as the compact disc (CD). The alternate embodiment detects run-lengths as a means of mapping characteristics or traits of optical media not limited to digital data formats.

Based upon the foregoing, it should be apparent that the invention may be implemented in a number of alternative ways. For example, detecting specific channel bit run-lengths in NRZI encoded data rather than NRZ encoded data and or applying the inventive method to other forms of optical media such as the CD. For example detecting one or more specific run-length as a means to locate and or quantify characteristics or traits of optical media not limited to digital data formats, such as optical disc analysis of biological samples. For example detecting one or more specific run-length as a means to locate and or quantify characteristics or traits of optical media not limited to digital data formats, such as optical disc analysis of chemical samples. For example detecting one or more specific run-length as a means to locate and or quantify characteristics or traits of optical media not limited to digital data formats, such as optical disc analysis of biochemical samples.

In one embodiment the error mapping control apparatus for a memory array incorporates a signal source for providing a stream of signals organized into a plurality of localized areas, a memory array means having a plurality of elements organized for storing error information from a plurality of localized areas from said signal source, said memory array means having a first input synchronizing signal for resetting said array to a first selected storage position of said memory array, said first selected position corresponds to said first localized area of said signal source being scanned for errors, means for identifying said first localized area by its fixed linear distance and fixed radial distance corresponding to said source, and memory control means for cycling said memory array means through successive array positions corresponding to successive localized areas of said signal source, for summing the errors collected from each of said successive localized area of said source and for storing said summation of said errors in a corresponding one of said elements of said array.

Another embodiment of the error mapping control apparatus for a memory array as described above, and further includes wherein said memory control means cycles said memory array means through successive array positions corresponding to localized areas of the object being scanned.

Another embodiment of the error mapping control apparatus for a memory array as described above, and further includes wherein each element of said array having a capacity to represent a plurality of separate signal levels and each signal level representing a corresponding number of error signals.

Another embodiment of the error mapping control apparatus for a memory array as described above, and further includes said signal source is a circular optical disc, each of said memory array elements being arranged in a predetermined pattern corresponding to said circular shape of said signal source, said identification means including further means for identifying successive localized areas on said source by further identifying a plurality of additional localized areas and each having a fixed linear distance and fixed radial distance from said first localized area, and means for summing the errors for each invalid symbol in each localized area from said source under the direction of said means for identification, and for storing said summation of said error signals from a plurality of invalid symbols into one of said multi level elements.

A further embodiment of the error mapping control apparatus for a memory array as described above, wherein said memory control means further employs a localized area identification means for identifying the number of tracks and the number of symbols from each track to be included in a localized area from an optical disc being scanned, and means for summing the errors collected from a localized area of said source under the direction of said localized area identification means, and for storing said summation of said error signals into one of said multi level elements.

A still further embodiment of the error mapping control apparatus for a memory array as described above, wherein said localized area identification means further employs sample size selector means for selecting the linear length of said localized area, and rotation count select circuit means for indicating the radial size of one of said localized areas.

A still further embodiment of the error mapping control apparatus for a memory array as described above, wherein said sample size selector means further employs register means responsive to clock signal pulses for defining the sample time period in which invalid symbols are detected by counting a selected number of channel bits and for generating an output sample size select enable control signal when said predetermined number of channel bits have been counted.

A further embodiment of the error mapping control apparatus for a memory array as described above, wherein said rotation count select circuit means further employs register means responsive to each tach signal received from the data source for indicating the radial size of one of said localized areas and for generating a rotation count select control signal for application to said memory array for providing al least one memory array input signal for selecting the next successive positioned memory array element as the storage location for errors detected in the next corresponding localized area.

In a second embodiment, an apparatus is provided for detecting at least one predetermined bit pattern in a digitally encoded bit stream, and the second embodiment incorporates a source of digitally encoded data, means, responsive to said source, for providing a bit stream having a sequence of at least digitally encoded bit patterns, said bit patterns having run-length restrictions, a symbol detector means, a data bus carrying said digitally encoded bit stream from said source to said symbol detector means, and said symbol detector means responsive to said bit patterns carried on said data bus for monitoring said bit stream substantially direct from said source of digitally encoded data and for identifying at least one predetermined bit pattern having run-length restriction from said digitally encoded bit pattern.

In a third embodiment, an apparatus is provided for detecting at least one predetermined bit pattern in a digitally encoded bit stream encoded with channel bit patterns employed to represent original data and the channel bit pattern have run-length restrictions, said third embodiment further incorporates a source of digitally encoded data, means, responsive to said source, for providing a sequence of digitally encoded bit stream patterns having at least channel bit patterns arranged as successive symbols, said symbols of channel bit patterns having run-length restrictions, a symbol detector means having at least one register employed for storing and detecting a specific run-length of channel bits in said bit stream, a data bus for carrying said digitally encoded bit stream from said source to said symbol detector means, said symbol detector means responsive to said data bus for monitoring said bit stream substantially direct from said source of said digitally encoded data and for identifying at least one symbol from said digitally encoded bit pattern.

A further embodiment for detecting at least one predetermined bit pattern in a digitally encoded bit stream encoded with channel bit patterns employed to represent original data and the channel bit pattern have run-length restrictions, as described above, wherein said symbol detector means further includes, at least one invalid sun-length mask register for providing a means for selecting at least one channel bit run-length that will be detected in the EFM+ bit stream.

A further embodiment of an error mapping control apparatus for a memory array as described above, and further includes tach bit setting means for setting the memory address back to the first location in the error mapping array.

A still further embodiment of an error mapping control apparatus for a memory array as described above, and further includes rotation count select circuit means for counting the radial track locations, and tach means for incrementing said rotation count select circuit means.

A further embodiment of an error mapping control apparatus for a memory array as described in the second example above, and further includes, a control and status register means for maintaining the status of said error map array.

Another embodiment of an error mapping control apparatus for a memory array as described in the second example above, and further including memory addressing means for automatically addressing individually selected positions for storing an indicator of the number of errors associated with each localized area, and display means responsive to the read out of individually selected elements in said memory array for displaying a visual indicator of the number of errors associated with each localized area.

In a third embodiment of an error mapping apparatus, such apparatus includes a source of digitally encoded data, means, responsive to said source, for providing a sequence of digitally encoded bit stream patterns having at least channel bit patterns arranged as successive symbols, said symbols of channel bit patterns having run-length restrictions, a plurality of memory elements arranged in a predetermined pattern corresponding to the shape of the object being examined, means for defining a plurality of localized areas within said shape, said shape being selected is a circular shape corresponding to an optical disc, means for defining each of said localized area by its lineal length and radial distance on said circular shape, means for identifying selected bit patterns originating in each localized area, each of said memory elements being employed for summing said identified bit patterns collected from each corresponding localized area and for storing said summation of said bit patterns in a corresponding memory element, and display means for displaying an indication of the sum of said identified bit patterns by said display means, whereby said sum is visually displayed by said display mean.

In a fourth embodiment, a method is described for identifying a predetermined invalid bit pattern in a digitally encoded bit stream, said method comprising the steps of, reading a bit stream having a plurality of valid channel bit patterns and invalid bit patterns employed for representing original data and the channel bit patterns have run-length restrictions and are arranged as successive symbols in the bit stream, providing at least one register for storing and detecting at least one specific invalid bit pattern of channel bits representing an invalid symbol, conveying the bit stream as read substantially directly from the reading of the bit stream to the storing of successive symbols in the bit stream, selectively gating successive symbols from the bit stream into the register substantially after the step of reading, comparing the valid symbol stored in the register with each successive symbol gated into the register, and generating a first error signal when the stored symbol fails to match the symbol gated into the register.

In a fifth embodiment, a method for capturing errors relative to their physical location on optical data media for creating an error map of the errors is described, and such a method comprises the steps of, reading a bit stream having a plurality of valid channel bit patterns and invalid bit patterns employed for representing original data and the channel bit patterns have run-length restrictions and are arranged as successive symbols in the bit stream, providing at least one register for storing and detecting at least one specific invalid bit pattern of channel bits representing an invalid symbol, conveying the bit stream as read substantially directly from the reading of the bit stream to the storing of successive symbols in the bit stream, selectively gating successive symbols from the bit stream into the register substantially after the step of reading, comparing the valid symbol stored in the register with each successive symbol gated into the register, generating a first error signal when the stored symbol fails to match the symbol gated into the register, providing a memory array having a plurality of addressable storage elements for storing error signals from a plurality of localized areas from the signal source, subdividing the bit stream into groupings of channel bit patterns associated with a localized area from said signal source, controllably addressing each storage element for summing all errors associated with each respective localized area, and displaying a representative sum of all errors detected from each localized area.

Having thus disclosed a preferred embodiment and alternate embodiments of the method and circuit of the invention, it being understood that these embodiments are not exhaustive of possible variations but merely exemplary of the inventor's creations.

What is claimed is:

1) Apparatus for detecting at least one predetermined invalid bit pattern in a digitally encoded bit stream, comprising:
a source of digitally encoded data;
means, responsive to said source, for providing a bit stream having a sequence of at least digitally encoded bit patterns;
said bit patterns having run-length restrictions;
an invalid symbol detector means;
a data bus carrying said digitally encoded bit stream from said source to said invalid symbol detector means; and
said invalid symbol detector means responsive to said bit patterns carried on said data bus for monitoring said bit stream substantially direct from said source of digitally encoded data and for identifying at least one invalid run-length restriction from said digitally encoded bit pattern.

2) Apparatus for detecting at least one predetermined invalid bit pattern in a digitally encoded bit stream as recited in claim 1 and further comprising:
said invalid symbol detector is employed for detecting errors at the run-length bit stream pattern level.

3) Apparatus for detecting at least one predetermined invalid bit pattern in a digitally encoded bit stream as recited in claim 1 and further comprising:
said invalid symbol detector is employed for detecting errors at the symbol level of the bit stream pattern.

4) Apparatus for detecting at least one predetermined bit pattern in a digitally encoded bit stream encoded with channel bit patterns employed to represent original data and the channel bit pattern have run-length restrictions, said apparatus comprising:
a source of digitally encoded data;
means, responsive to said source, for providing a sequence of digitally encoded bit stream patterns having at least channel bit patterns arranged as successive symbols;
said symbols of channel bit patterns having run-length restrictions;
a symbol detector means;
a data bus for carrying said digitally encoded bit stream from said source to said symbol detector means;
said symbol detector means responsive to said data bus for monitoring said bit stream substantially direct from said source of said digitally encoded data and for identifying at least one symbol from said digitally encoded bit pattern.

5) Apparatus for detecting at least one predetermined bit pattern in a digitally encoded bit stream encoded with channel bit patterns employed to represent original data and the channel bit pattern have run-length restrictions as recited in claim 4, said apparatus further comprising:
said symbol detector means reads the data before the data has been de-interleaved.

6) Apparatus for detecting at least one predetermined bit pattern in a digitally encoded bit stream encoded with channel bit patterns employed to represent original data and the channel bit pattern have run-length restrictions as recited in claim 4, said apparatus further comprising:
said symbol detector means reads the data before the data has been placed in ECC blocks.

7) Apparatus for detecting at least one predetermined bit pattern in a digitally encoded bit stream encoded with channel bit patterns employed to represent original data and the channel bit pattern have run-length restrictions as recited in claim 4, said apparatus further comprising:
said symbol detector means reads the data before the data has been processed with traditional error detection and correction circuits.

8) Apparatus for detecting at least one predetermined bit pattern as recited in claim 4 wherein said bit pattern is a valid bit pattern.

9) Apparatus for detecting at least one predetermined bit pattern as recited in claim 4 wherein said bit pattern is an invalid bit pattern.

10) An error mapping control apparatus for a memory array comprising:
a signal source for providing a stream of signals organized into a plurality of localized areas;
a memory array means having a plurality of elements organized for storing error information from a plurality of localized areas from said signal source;
said memory array means having a first input synchronizing signal for resetting said array to a first selected storage position of said memory array;
said first selected position corresponds to said first localized area of said signal source being scanned for errors;
means for identifying said first localized area by its fixed linear distance and fixed radial distance corresponding to said source; and
memory control means for cycling said memory array means through successive array positions corresponding to successive localized areas of said signal source, for summing the errors collected from each of said successive localized area of said source and for storing said summation of said errors in a corresponding one of said elements of said array;

11) An error mapping control apparatus for a memory array as recited in claim 10, wherein each element of said memory array further comprises:
a means for summing errors collected from a localized area defined by a selectable linear distance and a selectable radial distance within said data source.

12) An error mapping control apparatus for a memory array as recited in claim 10, and further comprising:
means for displaying the value in each element in said error map array as a representation of the number of errors associated with each corresponding localized area.

13) An error mapping control apparatus for a memory array as recited in claim 10, wherein said elements of said memory array further comprises:
each of said elements being employed for summing the number of errors found in each of said localized areas; and
the number of elements in the memory array is equal to the number of linear samples in each rotation of the optical media.

14) An error mapping control apparatus for a memory array as recited in claim 13, and further comprising:
means for displaying the value in each element in said error map array as a representation of the number of errors associated with each corresponding localized area.

15) An error mapping control apparatus for a memory array as recited in claim 10, and further comprising:
means for determining the radial resolution of elements of said array by the number of revolutions corresponding to each element.

16) An error mapping control apparatus for a memory array as recited in claim 15, and further comprising:
means for displaying the value in each element in said error map array as a representation of the number of errors associated with each corresponding localized area.

17) An error mapping control apparatus for a memory array as recited in claim 10, and further comprising:
means for incrementing the element value by the detection of an invalid symbol associated with a digital error during the reading of an localized area.

18) An error mapping control apparatus for a memory array as recited in claim 17, and further comprising:
means for displaying the value in each element in said error map array as a representation of the number of errors associated with each corresponding localized area.

19) An error mapping control apparatus for a memory array as recited in claim 10, and further comprising:
means for incrementing the element value by the detection of an invalid run-length associated with a digital error during the reading of an localized area.

20) An error mapping control apparatus for a memory array as recited in claim 19, and further comprising:
means for displaying the value in each element in said error map array as a representation of the number of errors associated with each corresponding localized area.
